(19) United States
(12) Patent Application Publication
(10) Pub. No.: US 2026/0057157 A1
(43) Pub. Date: Feb. 26, 2026

(54) METHOD OF OPTIMIZING STACKING ALGORITHM FOR SEMICONDUCTOR CHIPS, SYSTEM PERFORMING THE SAME, AND METHOD OF MANUFACTURING SEMICONDUCTOR DEVICE USING THE SAME

(71) Applicant: SAMSUNG ELECTRONICS CO., LTD., Suwon-si (KR)

(72) Inventors: Sungchul Kim, Suwon-si (KR); Youngjoo Lee, Suwon-si (KR); Sungjin Kim, Suwon-si (KR); Boosoo Ma, Suwon-si (KR); Narae Jeong, Suwon-si (KR)

(21) Appl. No.: 19/191,437

(22) Filed: Apr. 28, 2025

(30) Foreign Application Priority Data
Aug. 21, 2024 (KR) 10-2024-0111840

(51) Int. Cl. G06F 30/32; G01B 11/06; H01L 25/00; H10B 80/00

(52) U.S. Cl. CPC G06F 30/32; G01B 11/0608; H01L 25/50; H10B 80/00

(57) ABSTRACT

In a method of optimizing a stacking algorithm for semiconductor chips, measurement data are collected, using a measuring equipment, from wafers including semiconductor chips. Calculation data are obtained by pre-processing the measurement data. Global stress data associated with the wafers and local stress data associated with the semiconductor chips are obtained based on at least one of the measurement data and the calculation data. Stress characteristics associated with the semiconductor chips are predicted based on the global stress data and the local stress data. A stacking combination of the semiconductor chips is recommended based on the stress characteristics such that stacked chip structures satisfy at least one predetermined criterion. Each of the stacked chip structures is formed by stacking two or more of the semiconductor chips.

### CROSS-REFERENCE TO RELATED APPLICATION

This application claims priority under 35 USC § 119 to Korean Patent Application No. 10-2024-0111840 filed on Aug. 21, 2024, in the Korean Intellectual Property Office (KIPO), the contents of which are herein incorporated by reference in their entirety.

### BACKGROUND

A plurality of semiconductor chips may be manufactured by performing oxidation processes, photolithography processes, etching processes, deposition processes, ion implantation processes, metal wiring processes, etc. on semiconductor wafers. Depending on the design, a single semiconductor chip may include multiple layers that are stacked on one another, and/or multiple semiconductor chips may be stacked on one another. When stacking multiple semiconductor chips, issues such as warpage may arise from each semiconductor chip not being perfectly flat.

### SUMMARY

Semiconductor devices are becoming more compact while at the same time, performance demands such as capacity and speed are increasing. Reaching these goals, e.g., reduced size and improved performance, simultaneously can be difficult when there are non-uniformities in the wafers within the semiconductor devices.

Due to process dispersion, stress characteristics of semiconductor chips included in different wafers may be different from each other, and stress characteristics of semiconductor chips included in the same wafer may also be different from each other. As a result, when manufacturing a stacked chip structure by stacking semiconductor chips, the number of stacked chip structures that can be manufactured may be variously determined depending on the method and/or combination of stacking the semiconductor chips because stress characteristics of the semiconductor chips used for stacking are different from each other.

In the disclosed method of optimizing the stacking algorithm for the semiconductor chips, the stress characteristics such as warpage of each semiconductor chip may be efficiently predicted by utilizing patterned wafer geometry (PWG) data and local shape curvature (LSC) data of the wafer on which the fab-out process is completed. In addition, the optimal chip stacking combination may be efficiently proposed based on the predicted stress characteristics. Accordingly, when manufacturing the semiconductor device including the stacked chip structures, wasted semiconductor chips may be reduced or minimized, and the manufacturing yield may be improved or enhanced.

In some implementations, a method of optimizing a stacking algorithm for semiconductor chips efficiently predicts stress characteristics such as warpage of the semiconductor chips by a non-destructive scheme and efficiently provides an excellent stacking combination of the semiconductor chips.

In some implementations, a system performs the method of optimizing the stacking algorithm for the semiconductor chips.

In some implementations, a method of manufacturing a semiconductor device efficiently improves manufacturing yield using the method of optimizing the stacking algorithm for the semiconductor chips.

In a first general aspect, in a method of optimizing a stacking algorithm for semiconductor chips, a plurality of measurement data are collected, using a measuring equipment, from a plurality of wafers including a plurality of semiconductor chips. A plurality of calculation data are obtained by pre-processing the plurality of measurement data. A plurality of global stress data associated with the plurality of wafers and a plurality of local stress data associated with the plurality of semiconductor chips are obtained based on at least one of the plurality of measurement data and the plurality of calculation data. A plurality of stress characteristics associated with the plurality of semiconductor chips are predicted based on the plurality of global stress data and the plurality of local stress data. A stacking combination of the plurality of semiconductor chips is recommended based on the plurality of stress characteristics such that a plurality of stacked chip structures satisfy at least one predetermined criterion. Each of the plurality of stacked chip structures is formed by stacking two or more of the plurality of semiconductor chips.

In a second general aspect, a system includes a measuring equipment, at least one processor and a non-transitory computer readable medium. The measuring equipment collects a plurality of measurement data from a plurality of wafers including a plurality of semiconductor chips. The non-transitory computer readable medium stores program codes executed by the at least one processor. The at least one processor obtains a plurality of calculation data by pre-processing the plurality of measurement data, obtains a plurality of global stress data associated with the plurality of wafers and a plurality of local stress data associated with the plurality of semiconductor chips based on at least one of the plurality of measurement data and the plurality of calculation data, predicts a plurality of stress characteristics associated with the plurality of semiconductor chips based on the plurality of global stress data and the plurality of local stress data, and recommends a stacking combination of the plurality of semiconductor chips based on the plurality of stress characteristics such that a plurality of stacked chip structures satisfy at least one predetermined criterion. Each of the plurality of stacked chip structures is formed by stacking two or more of the plurality of semiconductor chips.

In a third general aspect, in a method of manufacturing a semiconductor device, a plurality of wafers including a plurality of semiconductor chips are fabricated. A stacking algorithm for the plurality of semiconductor chips is optimized. A semiconductor device including the plurality of semiconductor chips is fabricated based on the optimized stacking algorithm. When optimizing the stacking algorithm, a plurality of measurement data are collected, using a measuring equipment, from a plurality of wafers including a plurality of semiconductor chips. A plurality of calculation data are obtained by pre-processing the plurality of measurement data. A plurality of global stress data associated with the plurality of wafers and a plurality of local stress data associated with the plurality of semiconductor chips are obtained based on at least one of the plurality of measurement data and the plurality of calculation data. A plurality of stress characteristics associated with the plurality of semiconductor chips are predicted based on the plurality of global stress data and the plurality of local stress data. A stacking combination of the plurality of semiconductor chips is recommended based on the plurality of stress characteristics such that a plurality of stacked chip structures satisfy at least one predetermined criterion. Each of the plurality of stacked chip structures is formed by stacking two or more of the plurality of semiconductor chips.

In the method of optimizing the stacking algorithm for the semiconductor chips, the system and the method of manufacturing the semiconductor device, the stress characteristics such as warpage of each semiconductor chip may be efficiently predicted by utilizing the PWG data and the LSC data of the wafer on which the fab-out process is completed. In addition, the optimal chip stacking combination may be efficiently proposed based on the predicted stress characteristics. Accordingly, when manufacturing the semiconductor device including the stacked chip structures, wasted semiconductor chips may be reduced or minimized, and the manufacturing yield may be improved or enhanced.

### BRIEF DESCRIPTION OF THE DRAWINGS

FIG. 1 is a flowchart illustrating an example of a method of optimizing a stacking algorithm for semiconductor chips.

FIG. 2 is a diagram for describing an example of a method of optimizing a stacking algorithm for semiconductor chips.

FIGS. 3 and 4 are block diagrams illustrating an example of a system.

FIG. 5 is a flowchart illustrating an example of obtaining a plurality of global stress data and a plurality of local stress data in FIG. 1.

FIGS. 6 and 7 are diagrams for describing examples of collecting a plurality of measurement data, obtaining a plurality of calculation data, and obtaining a plurality of global stress data and a plurality of local stress data in FIG. 1.

FIG. 8 is a flowchart illustrating an example of predicting a plurality of stress characteristics in FIG. 1.

FIG. 9 is a diagram for describing an operation of FIG. 8.

FIG. 10 is a flowchart illustrating an example of predicting a plurality of stress characteristics in FIG. 1.

FIG. 11 is a diagram for describing an operation of FIG. 10.

FIG. 12 is a flowchart illustrating an example of recommending a stacking combination of a plurality of semiconductor chips in FIG. 1.

FIGS. 13A and 13B are flowcharts illustrating examples of determining whether a plurality of stacked chip structures satisfy a first criterion in FIG. 12.

FIGS. 14A, 14B and 14C are diagrams for describing operations of FIGS. 12, 13A and 13B.

FIG. 15 is a flowchart illustrating an example of recommending a stacking combination of a plurality of semiconductor chips in FIG. 1.

FIG. 16 is a flowchart illustrating an example of determining whether a plurality of stacked chip structures satisfy a second criterion in FIG. 15.

FIG. 17 is a flowchart illustrating an example of recommending a stacking combination of a plurality of semiconductor chips in FIG. 1.

FIGS. 18A and 18B are diagrams for describing an operation of FIG. 17.

FIGS. 19A and 19B are block diagrams illustrating examples of a semiconductor chip.

FIG. 20 is a flowchart illustrating an example of a method of manufacturing a semiconductor device.

FIG. 21 is a block diagram illustrating an example of a semiconductor device.

Like reference numerals refer to like elements throughout this application.

### DETAILED DESCRIPTION

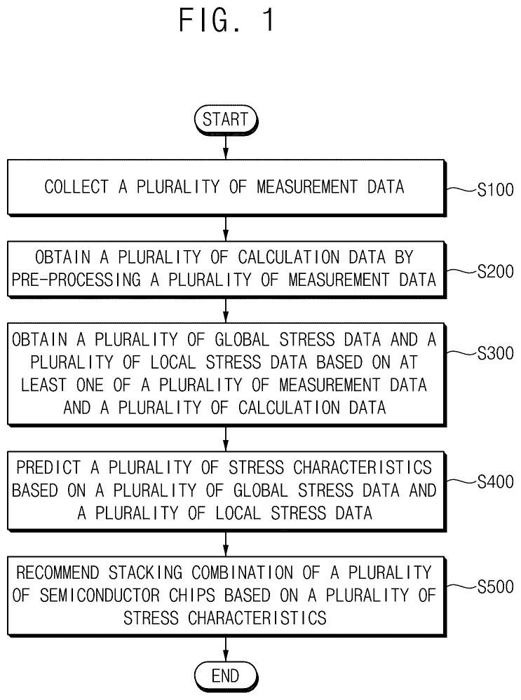

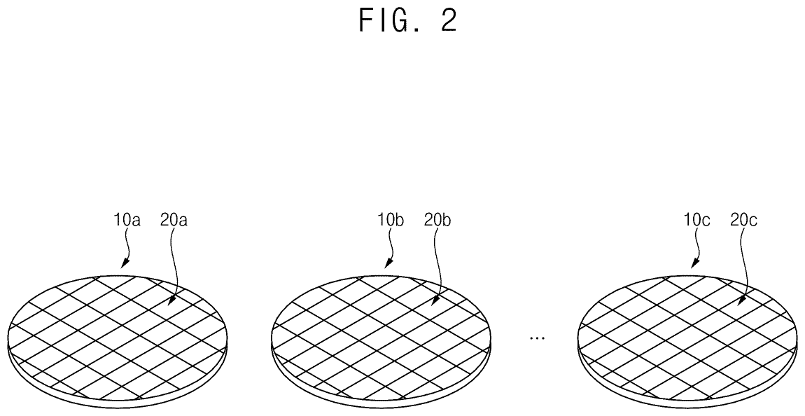

FIG. 1 is a flowchart illustrating an example of a method of optimizing a stacking algorithm for semiconductor chips. FIG. 2 is a diagram for describing an example of a method of optimizing a stacking algorithm for semiconductor chips.

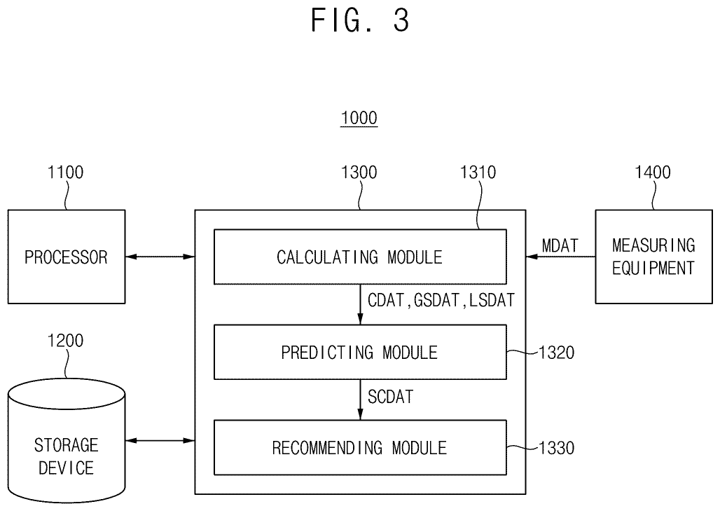

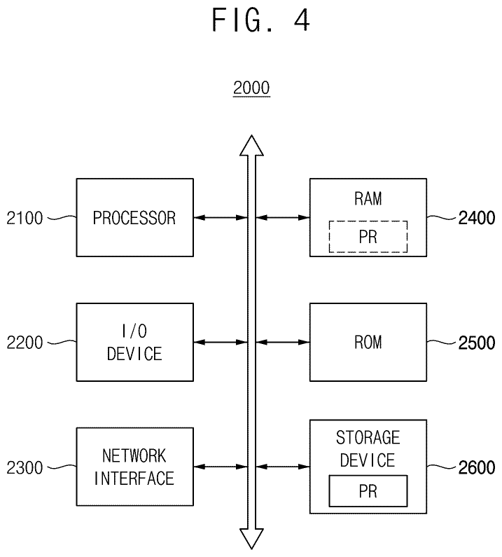

Referring to FIGS. 1 and 2, a method of optimizing a stacking algorithm for semiconductor chips is performed on a computer-based system and/or tool, at least part of which is implemented in hardware and/or software. For example, the system and/or tool may include a program (or program codes) that includes a plurality of instructions executed by at least one processor. The system and/or tool will be described with reference to FIGS. 3 and 4.

In the method of optimizing the stacking algorithm for the semiconductor chips, a plurality of measurement data are collecting, using a measuring equipment, from a plurality of wafers (or semiconductor wafers) including a plurality of semiconductor chips (operation S100), and a plurality of calculation data are obtained by pre-processing the plurality of measurement data (operation S200). For example, the plurality of wafers may be manufactured by performing various semiconductor processes such as an oxidation process, a photolithography process, an etching process, a deposition process, an ion implantation process, a metal wiring process, etc.

For example, as illustrated in FIG. 2, a plurality of wafers 10a, 10b and 10c may include a plurality of semiconductor chips 20a, 20b and 20c. For example, the wafer 10a may include the semiconductor chips 20a, the wafer 10b may include the semiconductor chips 20b, and the wafer 10c may include the semiconductor chips 20c. In other words, one wafer may be manufactured to include two or more semiconductor chips, and the number of the plurality of semiconductor chips 20a, 20b and 20c may be greater than the number of the plurality of wafers 10a, 10b and 10c.

In some implementations, each of the plurality of measurement data may be patterned wafer geometry (PWG) data, and each of the plurality of calculation data may be local shape curvature (LSC) data obtained by differentiating a respective one of the plurality of measurement data twice. Therefore, the number of the plurality of measurement data and the number of the plurality of calculation data may be equal to each other, e.g, the number of data points within the measurement data is the same as the number of data points within the calculation data. This number, e.g., of data points within either of the measurement data and calculation data, can be greater than or equal to the number of semiconductor chips.

A plurality of global stress data associated with the plurality of wafers and a plurality of local stress data associated with the plurality of semiconductor chips are obtained based on at least one of the plurality of measurement data and the plurality of calculation data (operation S300). In other words, global stress and local stress may be classified or segmented based on the pre-processed data. For example, one global stress data may be obtained for one wafer, and one local stress data may be obtained for one semiconductor chip. In other words, the number of the plurality of global stress data may be equal to the number of the plurality of wafers, and the number of the plurality of local stress data may be equal to the number of the plurality of semiconductor chips.

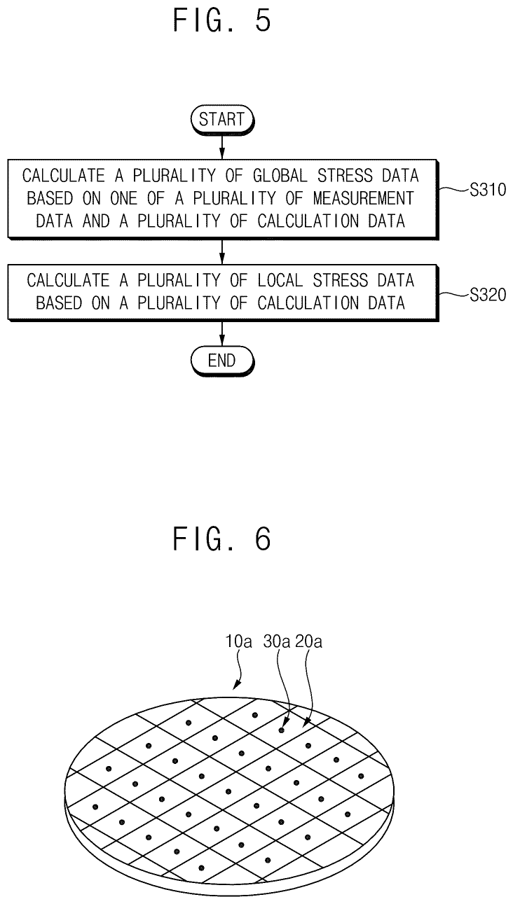

Operations S100, S200 and S300 will be described with reference to FIGS. 5 through 7.

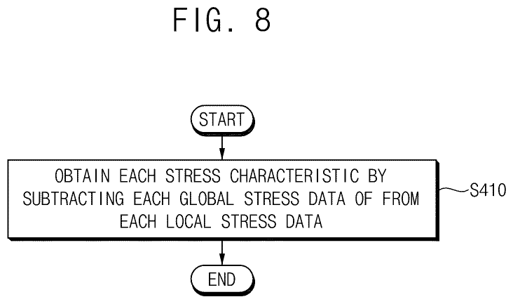

A plurality of stress characteristics associated with the plurality of semiconductor chips are predicted or estimated based on the plurality of global stress data and the plurality of local stress data (operation S400). For example, the plurality of stress characteristics may represent or indicate warpage (or bending) of the plurality of semiconductor chips, but examples are not limited thereto. Operation S400 will be described with reference to FIGS. 8 through 11.

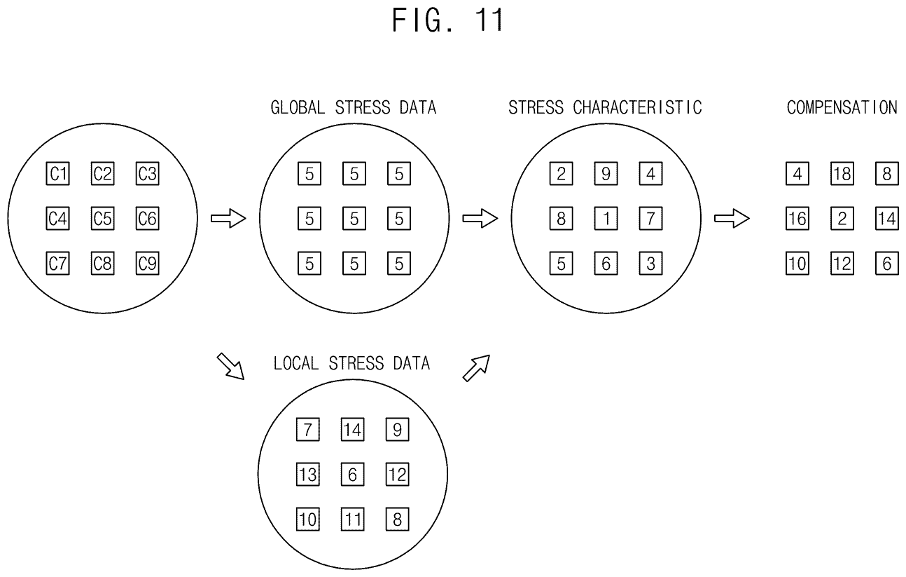

A stacking combination of the plurality of semiconductor chips is recommended based on the plurality of stress characteristics such that a plurality of stacked chip structures satisfy at least one predetermined criterion (operation S500). Each of the plurality of stacked chip structures is formed by stacking two or more of the plurality of semiconductor chips. For example, the at least one criterion may be associated with or related to thicknesses of the plurality of stacked chip structures. For example, the at least one criterion may be associated with or related to the sum of stress characteristics of semiconductor chips included in each stacked chip structure. However, examples are not limited thereto. Operation S500 will be described with reference to FIGS. 12 through 18.

In some implementations, operations of collecting the plurality of measurement data, obtaining the plurality of calculation data, obtaining the plurality of global stress data and the plurality of local stress data, predicting the plurality of stress characteristics, and recommending the stacking combination of the plurality of semiconductor chips may be performed before cutting the plurality of wafers to obtain the plurality of semiconductor chips. In other words, operation S100, S200, S300, S400 and S500 in FIG. 1 may be performed on the plurality of wafers by a non-destructive scheme, e.g., without cutting a wafer to divide the wafer into individual chips.

In some implementations, the plurality of semiconductor chips may include a plurality of memory chips, but examples are not limited thereto.

FIGS. 3 and 4 are block diagrams illustrating an example of a system.

Referring to FIG. 3, a system 1000 includes a processor 1100, a storage device 1200, a stacking algorithm optimizing module 1300 and a measuring equipment 1400.

Herein, the term “module” may indicate, but is not limited to, a software and/or hardware component, such as a field programmable gate array (FPGA) or an application specific integrated circuit (ASIC), which performs certain tasks. A “module” may be configured to reside in a tangible addressable storage medium and be configured to execute on one or more processors. For example, a “module” may include components such as software components, object-oriented software components, class components and task components, and processes, functions, Routines, segments of program code, drivers, firmware, microcode, circuitry, data, databases, data structures, tables, arrays, and variables. A “module” may be divided into a plurality of “modules” that perform detailed functions.

The processor 1100 may be used when the stacking algorithm optimizing module 1300 performs computations or calculations. For example, the processor 1100 may include a microprocessor, an application processor (AP), a central processing unit (CPU), a digital signal processor (DSP), a graphic processing unit (GPU), a neural processing unit (NPU), or the like. Although FIG. 3 illustrates that the system 1000 includes one processor 1100, examples are not limited thereto. For example, the system 1000 may include a plurality of processors. In addition, the processor 1100 may include cache memories to increase computation capacity.

The storage device 1200 may store data used for operations of the processor 1100 and the stacking algorithm optimizing module 1300. In some implementations, the storage device 1200 (or storage medium) may include any non-transitory computer-readable storage medium used to provide commands and/or data to a computer. For example, the non-transitory computer-readable storage medium may include a volatile memory such as a static random access memory (SRAM), a dynamic random access memory (DRAM), or the like, and a nonvolatile memory such as a flash memory, a magnetic random access memory (MRAM), a phase-change random access memory (PRAM), a resistive random access memory (RRAM), a ferroelectric random access memory (FRAM), or the like. The non-transitory computer-readable storage medium may be inserted into the computer, may be integrated in the computer, or may be coupled to the computer through a communication medium such as a network and/or a wireless link.

The measuring equipment 1400 collects a plurality of measurement data MDAT from a plurality of wafers including a plurality of semiconductor chips. For example, the measuring equipment 1400 may include or may be a non-destructive optical inspecting equipment that includes microscopes, cameras, and other systems that detect defects and measure dimensions in wafers and other components. In some implementations, the measuring equipment 1400 may be disposed or located outside the system 1000.

The stacking algorithm optimizing module 1300 may include a calculating module 1310, a predicting module 1320 and a recommending module 1330.

The calculating module 1310 obtains a plurality of calculation data CDAT by pre-processing the plurality of measurement data MDAT and obtains a plurality of global stress data GSDAT associated with the plurality of wafers and a plurality of local stress data LSDAT associated with the plurality of semiconductor chips based on at least one of the plurality of measurement data MDAT and the plurality of calculation data CDAT. In addition, the calculating module 1310 may perform various other calculations and/or computations.

The predicting module 1320 predicts a plurality of stress characteristics SCDAT associated with the plurality of semiconductor chips based on the plurality of global stress data GSDAT and the plurality of local stress data LSDAT.

The recommending module 1330 recommends a stacking combination of the plurality of semiconductor chips based on the plurality of stress characteristics SCDAT such that a plurality of stacked chip structures satisfy at least one predetermined criterion. Each of the plurality of stacked chip structures is formed by stacking two or more of the plurality of semiconductor chips.

As described above, the stacking algorithm optimizing module 1300 may operate in conjunction with the measuring equipment 1400 to perform the method of optimizing the stacking algorithm for the semiconductor chips of FIG. 1. For example, the measuring equipment 1400 may perform operation S100 in FIG. 1, the calculating module 1310 may perform operations S200 and S300 in FIG. 1, the predicting module 1320 may perform operation S400 in FIG. 1, and the recommending module 1330 may perform operation S500 in FIG. 1.

In some implementations, the calculating module 1310, the predicting module 1320 and the recommending module 1330 may be implemented as instructions or program codes that may be executed by the processor 1100. For example, the instructions or program codes of the calculating module 1310, the predicting module 1320 and the recommending module 1330 may be stored in computer readable medium. For example, the processor 1100 may load the instructions or program codes to a working memory (e.g., a DRAM, etc.).

In some implementations, the processor 1100 may be manufactured to efficiently execute instructions or program codes included in the calculating module 1310, the predicting module 1320 and the recommending module 1330. For example, the processor 1100 may efficiently execute the instructions or program codes from various artificial intelligence (AI) modules and/or machine learning modules. For example, the processor 1100 may receive information corresponding to the calculating module 1310, the predicting module 1320 and the recommending module 1330 to operate the calculating module 1310, the predicting module 1320 and the recommending module 1330.

In some implementations, the calculating module 1310, the predicting module 1320 and the recommending module 1330 may be implemented as a single integrated module. In some implementations, the calculating module 1310, the predicting module 1320 and the recommending module 1330 may be implemented as separate and different modules.

Referring to FIG. 4, a system 2000 includes a processor 2100, an input/output (I/O) device 2200, a network interface 2300, a random access memory (RAM) 2400, a read only memory (ROM) 2500 and a storage device 2600. FIG. 4 illustrates an example where all of the calculating module 1310, the predicting module 1320 and the recommending module 1330 in FIG. 3 are implemented in software. For convenience of illustration, a component corresponding to the measuring equipment 1400 in FIG. 3, which may be implemented as an equipment or facility separated from the system 2000, is omitted.

The system 2000 may be a computing system. For example, the computing system may be a fixed computing system such as a desktop computer, a workstation or a server, or may be a portable computing system such as a laptop computer.

The processor 2100 may be substantially the same as the processor 1100 in FIG. 3. For example, the processor 2100 may include a core or a processor core for executing an arbitrary instruction set (for example, intel architecture-32 (IA-32), 64 bit extension IA-32, x86-64, PowerPC, Sparc, MIPS, ARM, IA-64, etc.). For example, the processor 2100 may access a memory (e.g., the RAM 2400 or the ROM 2500) through a bus and may execute instructions stored in the RAM 2400 or the ROM 2500. As illustrated in FIG. 4, the RAM 2400 may store a program PR corresponding to the calculating module 1310, the predicting module 1320 and the recommending module 1330 in FIG. 3 or at least some elements of the program PR, and the program PR may allow the processor 2100 to perform operations for optimizing the stacking algorithm for the semiconductor chips (e.g., operations S100, S200, S300, S400 and S500 in FIG. 1).

In other words, the program PR may include a plurality of instructions and/or procedures executable by the processor 2100, and the plurality of instructions and/or procedures included in the program PR may allow the processor 2100 to perform the operations for optimizing the stacking algorithm for the semiconductor chips. Each of the procedures may denote a series of instructions for performing a certain task. A procedure may be referred to as a function, a routine, a subroutine, or a subprogram. Each of the procedures may process data provided from the outside and/or data generated by another procedure.

The storage device 2600 may be substantially the same as the storage device 1200 in FIG. 3. For example, the storage device 2600 may store the program PR. The program PR or at least some elements of the program PR may be loaded from the storage device 2600 to the RAM 2400 before being executed by the processor 2100. The storage device 2600 may store a file written in a program language, and the program PR generated by a compiler or the like or at least some elements of the program PR may be loaded to the RAM 2400.

The storage device 2600 may store data, which is to be processed by the processor 2100, or data obtained through processing by the processor 2100. The processor 2100 may process the data stored in the storage device 2600 to generate new data, based on the program PR and may store the generated data in the storage device 2600.

The I/O device 2200 may include an input device, such as a keyboard, a pointing device, or the like, and may include an output device such as a display device, a printer, or the like. For example, a user may trigger, through the I/O devices 2200, execution of the program PR by the processor 2100, and may provide or check various inputs, outputs and/or data, etc.

The network interface 2300 may provide access to a network outside the system 2000. For example, the network may include a plurality of computing systems and communication links, and the communication links may include wired links, optical links, wireless links, or arbitrary other type links. Various inputs may be provided to the system 2000 through the network interface 2300, and various outputs may be provided to another computing system through the network interface 2300.

In some implementations, the computer program codes, the calculating module 1310, the predicting module 1320 and the recommending module 1330 may be stored in a transitory or non-transitory computer readable medium. In some implementations, values obtained from arithmetic processing performed by the processor may be stored in a transitory or non-transitory computer readable medium. In some implementations, intermediate values generated during the training operation may be stored in a transitory or non-transitory computer readable medium. In some implementations, various data such as measurement data, calculation data, global stress data, local stress data and/or stress characteristics may be stored in a transitory or non-transitory computer readable medium. However, examples are not limited thereto.

FIG. 5 is a flowchart illustrating an example of obtaining a plurality of global stress data and a plurality of local stress data in FIG. 1.

Referring to FIGS. 1 and 5, when obtaining the plurality of global stress data and the plurality of local stress data (operation S300), the plurality of global stress data may be calculated based on at least one of the plurality of measurement data or the plurality of calculation data (operation S310), and the plurality of local stress data may be calculated based on the plurality of calculation data (operation S320). For example, one global stress data may be obtained for one wafer, and one local stress data may be obtained for one semiconductor chip.

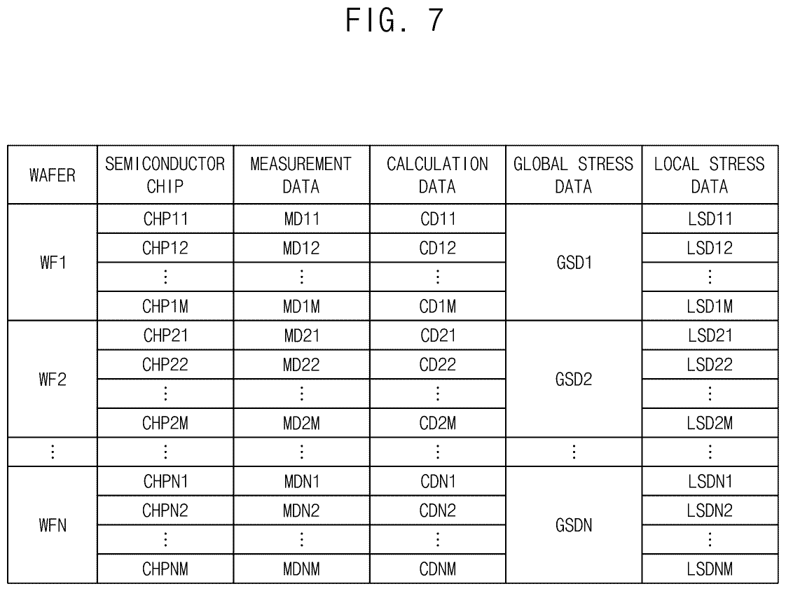

FIGS. 6 and 7 are diagrams for describing examples of collecting a plurality of measurement data, obtaining a plurality of calculation data, and obtaining a plurality of global stress data and a plurality of local stress data in FIG. 1.

Referring to FIGS. 1, 6 and 7, when collecting the plurality of measurement data (operation S100), measurement data may be obtained from measurement locations 30a on a wafer 10a. For example, one measurement data may be obtained from one measurement location. For example, each measurement data may be PWG data. For example, one measurement data (e.g., first measurement data) may include or correspond to a height value at one measurement location (e.g., first measurement location) of the wafer 10a, e.g., a height from a reference plane to an upper surface of the wafer 10a at the one measurement location.

As illustrated in FIG. 6, one measurement location may be set on one semiconductor chip, and one measurement data may be obtained from one measurement location. In other words, the number of the measurement locations 30a and the number of the measurement data may be equal to the number of semiconductor chips 20a. For example, as illustrated in FIG. 7, measurement data MD11, MD12, . . . , MD1M may be obtained for M semiconductor chips CHP11, CHP12, . . . , CHP1M included in a first wafer WF1, measurement data MD21, MD22, . . . , MD2M may be obtained for M semiconductor chips CHP21, CHP22, . . . , CHP2M included in a second wafer WF2, and measurement data MDN1, MDN2, . . . , MDNM may be obtained for M semiconductor chips CHPN1, CHPN2, . . . , CHPNM included in an N-th wafer WFN, where each of M and N is a positive integer.

However, examples are not limited thereto. For example, two or more measurement locations may be set on one semiconductor chip, and the number of the measurement data may be greater than the number of the semiconductor chips. In addition, although the same number of measurement locations are set on all semiconductor chips in the present example, different number of measurement locations may be set on the semiconductor chips.

Thereafter, when obtaining the plurality of calculation data (operation S200), one calculation data may be generated based on one measurement data. For example, each calculation data may be LSC data. For example, one calculation data (e.g., first calculation data) may be obtained by differentiating the one measurement data (e.g., the first measurement data) twice. Therefore, the number of the plurality of measurement data and the number of the plurality of calculation data may be equal to each other.

For example, as illustrated in FIG. 7, calculation data CD11, CD12, . . . , CD1M may be obtained by second-differentiating the measurement data MD11, MD12, . . . , MD1M collected from the first wafer WF1, calculation data CD21, CD22, . . . , CD2M may be obtained by second-differentiating the measurement data MD21, MD22, . . . , MD2M collected from the second wafer WF2, and calculation data CDN1, CDN2, . . . , CDNM may be obtained by second-differentiating the measurement data MDN1, MDN2, . . . , MDNM collected from the N-th wafer WFN.

However, examples are not limited thereto. For example, as described above, the number of the plurality of measurement data and the number of the plurality of calculation data may be equal to each other, the number of the plurality of measurement data may be greater than or equal to the number of the plurality of semiconductor chips, and thus the number of the plurality of calculation data may also be greater than or equal to the number of the plurality of semiconductor chips.

The LSC data (or value) may represent the second derivative of the PWG data (or value), e.g., the curvature data. For example, the LSC data may be obtained based on Equation 1 and Equation 2. For example, the LSC data may be inversely proportional to the radius of curvature 1/R, and may be proportional to the stress.

$$L S {C}_{x} = \frac{{d}^{2}}{d {x}^{2}} Z ( x , y ) \qquad [ Equation 1 ]$$

$$LS {C}_{y} = \frac{{d}^{2}}{d {y}^{2}} Z ( x , y ) \qquad [ Equation 2 ]$$

In the mechanics of materials, it may be assumed that the changes in deflection and deflection angle are approximate to each other because the changes in shape of the members are very small. Rdθ=ds by the formula for the arc of the circular sector, where R is the radius of curvature of the wafer, and s is the arc length in radians, and θ is the angle in radians. Thus, the curvature k of the wafer may be expressed as

$$κ = \frac{1}{R} = \frac{d θ}{ds} .$$

In addition, when θ is small,

$$tan θ = \frac{d v}{d x} \approx θ , and κ = \frac{M}{EI} ,$$

where v is the deflection, M is the bending moment, E is Young's module, and I is the second moment of area of the beam cross-section about the axis of interest. Thus, Equation 3 and Equation 4 may be obtained.

$$κ = \frac{1}{R} = \frac{d θ}{ds} = \frac{d}{d x} ( \frac{d v}{d x} ) = \frac{{d}^{2} v}{{dx}^{2}} = \frac{M}{EI} \qquad [ Equation 3 ]$$

$${v}^{″} = \frac{{d}^{2} v}{{dx}^{2}} = \frac{1}{R} \qquad [ Equation 4 ]$$

Additionally, Stoney's Equation (recited below in Equation 5) indicates that the stress of the thin film is proportional to the curvature (e.g., 1/R) of the wafer.

$${σ}_{f} = \frac{{E}_{s} {t}_{s}^{2}}{6 ( 1 - {v}_{s} ) {t}_{f}} ( \frac{1}{R} - \frac{1}{{R}_{0}} ) \qquad [ Equation 5 ]$$

In Equation 5, σ_{f} denotes the stress of the thin film, t_{f} denotes the thickness of the thin film, vs denotes Poisson's ratio of silicon, Eₛ denotes the elastic modulus of silicon, tₛ denotes the thickness of silicon, R₀ denotes the initial curvature of the wafer, and R denotes the curvature of the wafer. The equibiaxial wafer stress may be calculated using Stoney's Equation, and the stress data may be efficiently obtained using the LSC data.

However, examples are not limited thereto. For example, at least one of various Equations other than Stoney's Equation may be used to determine the relationship between stress and curvature, and at least one of various stresses other than the equibiaxial wafer stress may be calculated.

Thereafter, when obtaining the plurality of global stress data and the plurality of local stress (operation S300), one global stress data may be generated for each wafer based on the measurement data or the calculation data, and one local stress data may be generated for each semiconductor chip based on the calculation data.

For example, as illustrated in FIG. 7, global stress data GSD1 for the first wafer WF1 may be obtained based on the measurement data MD11, MD12, . . . , MDIM or the calculation data CD11, CD12, . . . , CD1M, global stress data GSD2 for the second wafer WF2 may be obtained based on the measurement data MD21, MD22, . . . , MD2M or the calculation data CD21, CD22, . . . , CD2M, and global stress data GSDN for the N-th wafer WFN may be obtained based on the measurement data MDN1, MDN2, . . . , MDNM or the calculation data CDN1, CDN2, . . . , CDNM.

In addition, as illustrated in FIG. 7, local stress data LSD11, LSD12, . . . , LSD1M for the M semiconductor chips CHP11, CHP12, . . . , CHP1M included in the first wafer WF1 may be obtained based on the calculation data CD11, CD12, . . . , CD1M, local stress data LSD21, LSD22, . . . , LSD2M for the semiconductor chips CHP21, CHP22, . . . , CHP2M included in the second wafer WF2 may be obtained based on the calculation data CD21, CD22, . . . , CD2M, and local stress data LSDN1, LSDN2, . . . , LSDNM for the M semiconductor chips CHPN1, CHPN2, . . . , CHPNM included in the N-th wafer WFN may be obtained based on the calculation data CDN1, CDN2, . . . , CDNM.

Therefore, semiconductor chips included in the same wafer may have the same global stress data, and semiconductor chips may have different local stress data. For example, the semiconductor chips CHP11, CHP12, . . . , CHP1M included in the first wafer WF1 may have the same global stress data GSD1 and different local stress data LSD11, LSD12, . . . , LSD1M.

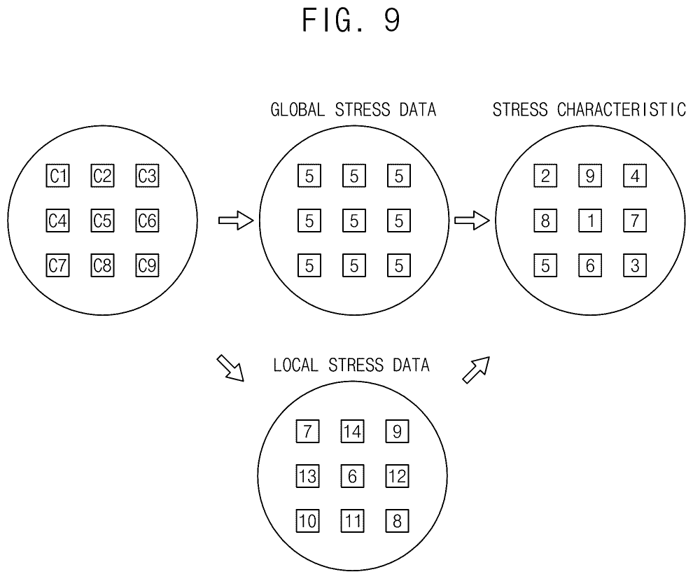

FIG. 8 is a flowchart illustrating an example of predicting a plurality of stress characteristics in FIG. 1. FIG. 9 is a diagram for describing an operation of FIG. 8.

Referring to FIGS. 1 and 8, when predicting the plurality of stress characteristics (operation S400), a stress characteristic of each semiconductor chip may be obtained by subtracting global stress data of each wafer including each semiconductor chip from local stress data of each semiconductor chip (operation S410). For example, a first stress characteristic of a first semiconductor chip may be obtained by subtracting first global stress data of a first wafer including the first semiconductor chip from first local stress data of the first semiconductor chip.

Referring to FIG. 9, an example where one wafer includes nine semiconductor chips C1, C2, C3, C4, C5, C6, C7, C8 and C9 and stress characteristics are predicted for each of the semiconductor chip C1, C2, C3, C4, C5, C6, C7, C8 and C9 is illustrated.

For example, global stress data of the first to ninth semiconductor chips C1, C2, C3, C4, C5, C6, C7, C8 and C9 may have the same value of “5”. For example, local stress data of the first semiconductor chip C1 may have a value of “7”, local stress data of the second semiconductor chip C2 may have a value of “14”, local stress data of the third semiconductor chip C3 may have a value of “9”, local stress data of the fourth semiconductor chip C4 may have a value of “13”, local stress data of the fifth semiconductor chip C5 may have a value of “6,” local stress data of the sixth semiconductor chip C6 may have a value of “12”, local stress data of the seventh semiconductor chip C7 may have a value of “10”, local stress data of the eighth semiconductor chip C8 may have a value of “11”, and local stress data of the ninth semiconductor chip C9 may have a value of “8”.

For example, when operation S410 in FIG. 8 is performed, a stress characteristic of the first semiconductor chip C1 may have a value of “2” (=7-5), a stress characteristic of the second semiconductor chip C2 may have a value of “9” (=14-5), a stress characteristic of the third semiconductor chip C3 may have a value of “4” (=9-5), a stress characteristic of the fourth semiconductor chip C4 may have a value of “8” (=13-5), a stress characteristic of the fifth semiconductor chip C5 may have a value of “1” (=6-5), a stress characteristic of the sixth semiconductor chip C6 may have a value of “7” (=12-5), a stress characteristic of the seventh semiconductor chip C7 may have a value of “5” (=10-5), a stress characteristic of the eighth semiconductor chip C8 may have a value of “6” (=11-5), and a stress characteristic of the ninth semiconductor chip C9 may have a value of “3” (=8-5).

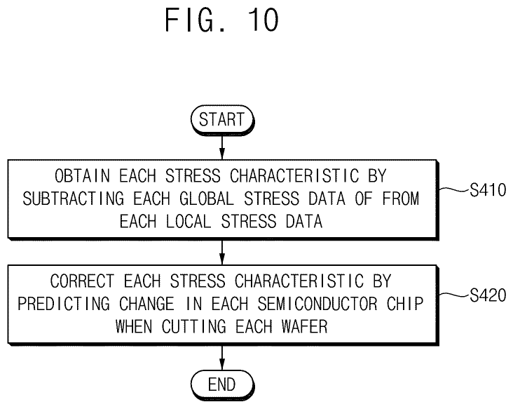

FIG. 10 is a flowchart illustrating an example of predicting a plurality of stress characteristics in FIG. 1. FIG. 11 is a diagram for describing an operation of FIG. 10. The descriptions repeated with or overlapping with descriptions of FIGS. 8 and 9 will be omitted in the interest of brevity.

Referring to FIGS. 1 and 10, when predicting the plurality of stress characteristics (operation S400), operation S410 may be substantially the same as that described with reference to FIG. 8. The stress characteristic of each semiconductor chip may be corrected or compensated by predicting a change in each semiconductor chip when cutting each wafer to obtain each semiconductor chip (operation S420). For example, the first stress characteristic of the first semiconductor chip may be corrected, e.g., updated, by predicting a change in the first semiconductor chip when cutting the first wafer including the first semiconductor chip to obtain the first semiconductor chip. For example, the stress characteristic (e.g., warpage, etc.) of each semiconductor chip after each semiconductor chip is separated from the wafer may be predicted by reflecting the stress distribution, the thin film structure, the film properties, etc. obtained from the LSC data.

Referring to FIG. 11, an example where stress characteristics are predicted for each of the semiconductor chip C1, C2, C3, C4, C5, C6, C7, C8 and C9 included in one wafer is illustrated. The global stress data, the local stress data and the results of performing operation S410 may be substantially the same as those described above with reference to FIG. 9.

For example, when operation S420 in FIG. 10 is performed, it may be predicted or estimated that the stress characteristic of each semiconductor chip will double when cutting the wafer. For example, a corrected stress characteristic of the first semiconductor chip C1 may have a value of “4” (=2*2), a corrected stress characteristic of the second semiconductor chip C2 may have a value of “18” (=9*2), a corrected stress characteristic of the third semiconductor chip C3 may have a value of “8” (=4*2), a corrected stress characteristic of the fourth semiconductor chip C4 may have a value of “16” (=8*2), a corrected stress characteristic of the fifth semiconductor chip C5 may have a value of “2” (=1*2), a corrected stress characteristic of the sixth semiconductor chip C6 may have a value of “14” (=7*2), a corrected stress characteristic of the seventh semiconductor chip C7 may have a value of “10” (=5*2), a corrected stress characteristic of the eighth semiconductor chip C8 may have a value of “12” (=6*2), and a corrected stress characteristic of the ninth semiconductor chip C9 may have a value of “6” (=3*2).

Although examples are described based on a specific number of semiconductor chips and specific numerical stress characteristics, the present disclosure is not limited thereto.

FIG. 12 is a flowchart illustrating an example of recommending a stacking combination of a plurality of semiconductor chips in FIG. 1.

Referring to FIGS. 1 and 12, when recommending the stacking combination of the plurality of semiconductor chips (operation S500), the plurality of stacked chip structures may be formed (operation S510). Each of the plurality of stacked chip structures may be formed by stacking two or more of the plurality of semiconductor chips. For example, a first stacked chip structure including first semiconductor chips and a second stacked chip structure including second semiconductor chips may be formed. For example, the number of semiconductor chips included in one stacked chip structure may be predetermined.

It may be determined whether the plurality of stacked chip structures formed in operation S510 satisfy a first criterion (or whether the first criterion is satisfied by the plurality of stacked chip structures formed in operation S510) (operation S520). For example, the first criterion may be associated with the thicknesses of the plurality of stacked chip structures and may be associated with the sum of the stress characteristics of the semiconductor chips included in each stacked chip structure.

When the plurality of stacked chip structures satisfy the first criterion (operation S520: YES), e.g., in response to determining that the plurality of stacked chip structures satisfy the first criterion, the plurality of stacked chip structures formed in operation S510 may be provided as the stacking combination of the plurality of semiconductor chips (operation S540). For example, the stacking combination of the plurality of semiconductor chips may be provided in a user interface on a device such that the stacking combination includes the first stacked chip structure and the second stacked chip structure. In some implementations, the provided stacking combination of the plurality of semiconductor chips is used to form a semiconductor device according to the stacking combination.

When the plurality of stacked chip structures do not satisfy the first criterion (operation S520: NO), operations S510 and S520 may be repeatedly performed until the first criterion is satisfied.

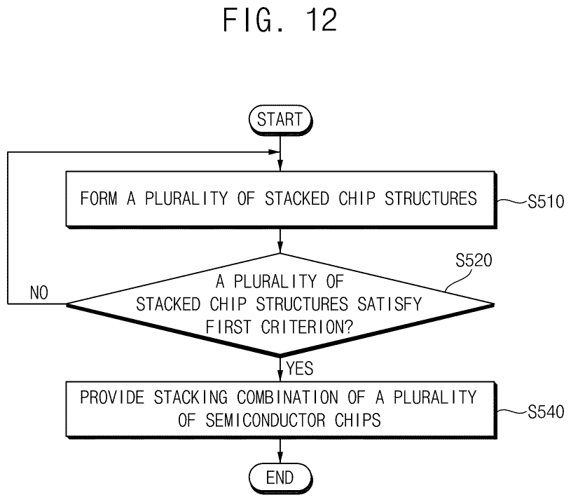

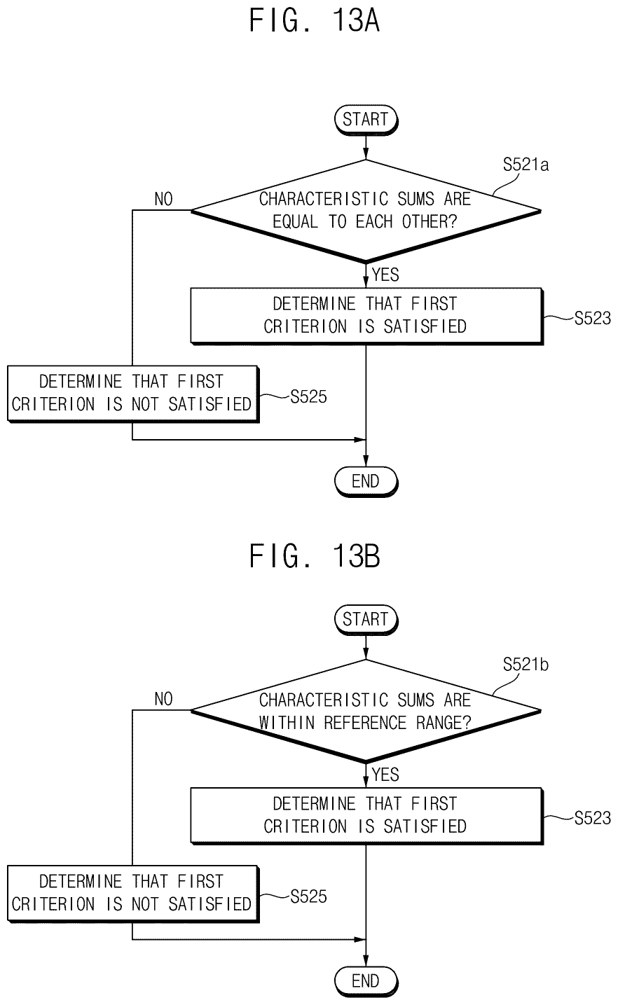

FIGS. 13A and 13B are flowcharts illustrating examples of determining whether a plurality of stacked chip structures satisfy a first criterion in FIG. 12.

Referring to FIGS. 12 and 13A, when determining whether the plurality of stacked chip structures satisfy the first criterion (operation S520), it may be determined whether characteristic sums of the plurality of stacked chip structures are equal to each other (operation S521a). Each of the characteristic sums may correspond to the sum of stress characteristics of semiconductor chips included in each stacked chip structure. For example, it may be determined or checked whether a first characteristic sum and a second characteristic sum are equal to each other, the first characteristic sum may correspond to the sum of stress characteristics of the first semiconductor chips included in the first stacked chip structure, and the second characteristic sum may correspond to the sum of stress characteristics of the second semiconductor chips included in the second stacked chip structure.

When all of the characteristic sums of the plurality of stacked chip structures are equal to each other (operation S521a: YES), e.g., when the first characteristic sum and the second characteristic sum are equal to each other, it may be determined that the plurality of stacked chip structures satisfy the first criterion (operation S523).

When at least some of the characteristic sums of the plurality of stacked chip structures are different from each other (operation S521a: NO), e.g., when the first characteristic sum and the second characteristic sum are different from each other, it may be determined that the plurality of stacked chip structures do not satisfy the first criterion (operation S525).

Referring to FIGS. 12 and 13B, when determining whether the plurality of stacked chip structures satisfy the first criterion (operation S520), it may be determined whether the characteristic sums of the plurality of stacked chip structures are within a predetermined reference range (operation S521b). For example, it may be determined or checked whether each of the first characteristic sum and the second characteristic sum is within the reference range.

When all of the characteristic sums of the plurality of stacked chip structures are within the reference range (operation S521b: YES), e.g., when both the first characteristic sum and the second characteristic sum have values within the reference range, it may be determined that the plurality of stacked chip structures satisfy the first criterion (operation S523).

When at least some of the characteristic sums of the plurality of stacked chip structures are out of the reference range (operation S521b: NO), e.g., when at least one of the first characteristic sum and the second characteristic sum is out of the reference range, it may be determined that the plurality of stacked chip structures do not satisfy the first criterion (operation S525).

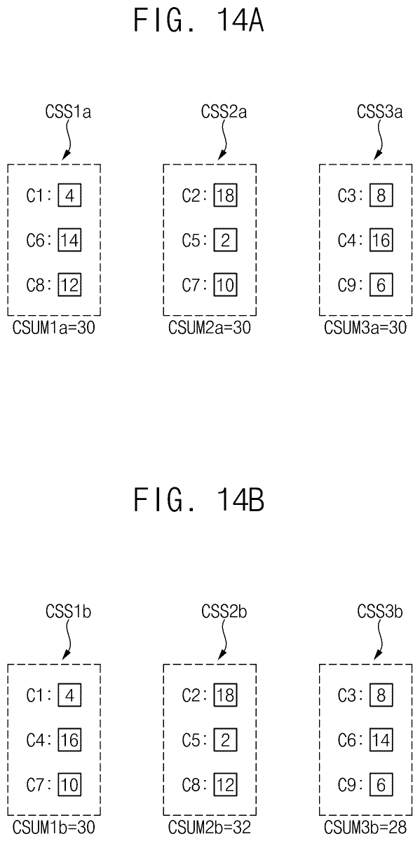

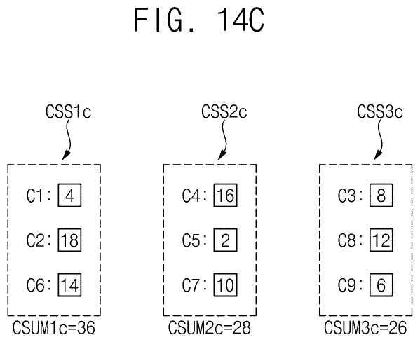

FIGS. 14A, 14B and 14C are diagrams for describing operations of FIGS. 12, 13A and 13B.

Referring to FIGS. 14A, 14B and 14C, examples where stacked chip structures are formed using the semiconductor chips C1, C2, C3, C4, C5, C6, C7, C8 and C9 for which the stress characteristics are predicted as illustrated in FIG. 11 are illustrated, and examples where one stacked chip structure includes three semiconductor chips are illustrated.

For example, as illustrated in FIG. 14A, a first stacked chip structure CSS1a may be formed by stacking the first, sixth and eighth semiconductor chips C1, C6 and C8, a second stacked chip structure CSS2a may be formed by stacking the second, fifth and seventh semiconductor chips C2, C5 and C7, and a third stacked chip structure CSS3a may be formed by stacking the third, fourth and ninth semiconductor chips C3, C4 and C9. In this example, a first characteristic sum CSUM1a of the first stacked chip structure CSS1a may have a value of “30” (=4+14+12), a second characteristic sum CSUM2a of the second stacked chip structure CSS2a may have a value of “30” (=18+2+10), and a third characteristic sum CSUM3a of the third stacked chip structure CSS3a may have a value of “30” (=8+16+6).

For example, as illustrated in FIG. 14B, a first stacked chip structure CSS1b may be formed by stacking the first, fourth and seventh semiconductor chips C1, C4 and C7, a second stacked chip structure CSS2b may be formed by stacking the second, fifth and eighth semiconductor chips C2, C5 and C8, and a third stacked chip structure CSS3b may be formed by stacking the third, sixth and ninth semiconductor chips C3, C6 and C9. In this example, a first characteristic sum CSUM1b of the first stacked chip structure CSS1b may have a value of “30” (=4+16+10), a second characteristic sum CSUM2b of the second stacked chip structure CSS2b may have a value of “32” (=18+2+12), and a third characteristic sum CSUM3b of the third stacked chip structure CSS3b may have a value of “28” (=8+14+6).

For example, as illustrated in FIG. 14C, a first stacked chip structure CSS1b may be formed by stacking the first, second and sixth semiconductor chips C1, C2 and C6, a second stacked chip structure CSS2b may be formed by stacking the fourth, fifth and seventh semiconductor chips C4, C5 and C7, and a third stacked chip structure CSS3b may be formed by stacking the third, eighth, and ninth semiconductor chips C3, C8 and C9. In this example, a first characteristic sum CSUM1c of the first stacked chip structure CSS1c may have a value of “36” (=4+18+14), a second characteristic sum CSUM2c of the second stacked chip structure CSS2c may have a value of “28” (=16+2+12), and a third characteristic sum CSUM3c of the third stacked chip structure CSS3c may have a value of “26” (=8+12+6).

In some implementations, when operations in FIGS. 12 and 13A are performed on the examples of FIGS. 14A, 14B, and 14C, it may be determined that the stacked chip structures CSS1a, CSS2a and CSS3a in FIG. 14A satisfy the first criterion, and it may be determined that the stacked chip structures CSS1b, CSS2b and CSS3b in FIG. 14B and the stacked chip structures CSS1c, CSS2c and CSS3c in FIG. 14C do not satisfy the first criterion.

In some implementations, when operations in FIGS. 12 and 13B are performed on the examples of FIGS. 14A, 14B, and 14C, and when the reference range corresponds to a range greater than or equal to 28 and less than or equal to 32, it may be determined that the stacked chip structures CSS1a, CSS2a and CSS3a in FIG. 14A and the stacked chip structures CSS1b, CSS2b and CSS3b in FIG. 14B satisfy the first criterion, and it may be determined that the stacked chip structures CSS1c, CSS2c and CSS3c in FIG. 14C do not satisfy the first criterion.

Although the examples use a specific number of semiconductor chips, specific numerical stress characteristics and a specific reference range, the present disclosure is not limited thereto.

FIG. 15 is a flowchart illustrating an example of recommending a stacking combination of a plurality of semiconductor chips in FIG. 1. The descriptions repeated with or overlapping with descriptions of FIG. 12 will be omitted in the interest of brevity.

Referring to FIGS. 1 and 15, when recommending the stacking combination of the plurality of semiconductor chips (operation S500), operations S510 and S520 may be substantially the same as those described with reference to FIG. 12.

It may be determined whether the plurality of stacked chip structures formed in operation S510 satisfy a second criterion (or whether the second criterion is satisfied by the plurality of stacked chip structures formed in operation S510) (operation S530). For example, the second criterion may be associated with a specification of the semiconductor device including the plurality of stacked chip structures. For example, as with the first criterion, the second criterion may be associated with the thicknesses of the plurality of stacked chip structures and may be associated with the sum of the stress characteristics of the semiconductor chips included in each stacked chip structure.

When the plurality of stacked chip structures satisfy both the first criterion and the second criterion (operation S520: YES & operation S530: YES), the plurality of stacked chip structures formed in operation S510 may be provided as the stacking combination of the plurality of semiconductor chips (operation S540). Operation S540 may be substantially the same as that described with reference to FIG. 12.

When the plurality of stacked chip structures do not satisfy the first criterion and/or the second criterion (operation S520: NO and/or operation S530: NO), operations S510, S520 and S530 may be repeatedly performed until both the first criterion and the second criterion are satisfied.

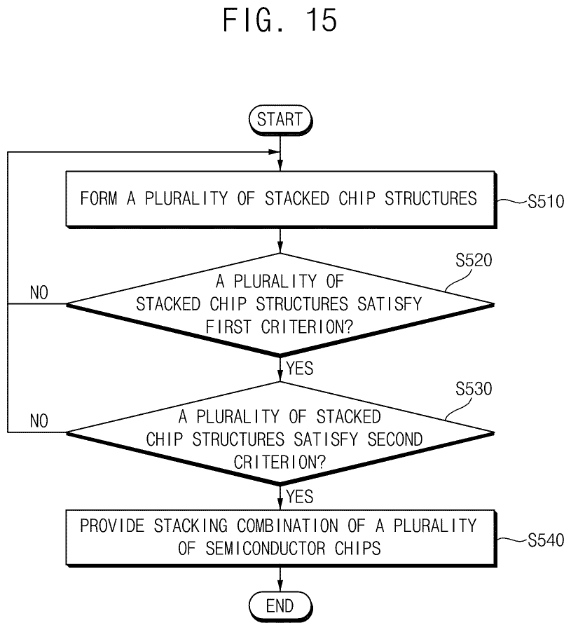

FIG. 16 is a flowchart illustrating an example of determining whether a plurality of stacked chip structures satisfy a second criterion in FIG. 15.

Referring to FIGS. 15 and 16, when determining whether the plurality of stacked chip structures satisfy the second criterion (operation S530), it may be determined whether the characteristic sums of the plurality of stacked chip structures are less than a predetermined reference value (operation S531). For example, it may be determined or checked whether each of the first characteristic sum and the second characteristic sum is less than the reference value.

When all of the characteristic sums of the plurality of stacked chip structures are less than the reference value (operation S531: YES), e.g., when both the first characteristic sum and the second characteristic sum are less than the reference value, it may be determined that the plurality of stacked chip structures satisfy the second criterion (operation S533).

When at least some of the characteristic sums of the plurality of stacked chip structures are greater than or equal to the reference value (operation S531: NO), e.g., when at least one of the first characteristic sum and the second characteristic sum is greater than or equal to the reference value, it may be determined that the plurality of stacked chip structures do not satisfy the second criterion (operation S535).

In some implementations, when operations of FIGS. 12, 13A, 15 and 16 are performed on the examples of FIGS. 14A, 14B, and 14C, and when the reference value corresponds to 32, it may be determined that the stacked chip structures CSS1a, CSS2a and CSS3a in FIG. 14A satisfy both the first criterion and the second criterion, and it may be determined that the stacked chip structures CSS1b, CSS2b and CSS3b in FIG. 14B and the stacked chip structures CSS1c, CSS2c and CSS3c in FIG. 14C do not satisfy both the first criterion and the second criterion.

In some implementations, when operations in FIGS. 12 and 13B are performed on the examples of FIGS. 14A, 14B, and 14C, when the reference range corresponds to a range greater than or equal to 28 and less than or equal to 32, and the reference value corresponds to 32, it may be determined that the stacked chip structures CSS1a, CSS2a and CSS3a in FIG. 14A satisfy both the first criterion and the second criterion, it may be determined that the stacked chip structures CSS1b, CSS2b and CSS3b in FIG. 14B satisfy the first criterion but do not satisfy the second criterion, and it may be determined that the stacked chip structures CSS1c, CSS2c and CSS3c in FIG. 14C do not satisfy both the first criterion and the second criterion.

Although the examples use a specific number of semiconductor chips, specific numerical stress characteristics, a specific reference range and a specific reference value, the present disclosure is not limited thereto.

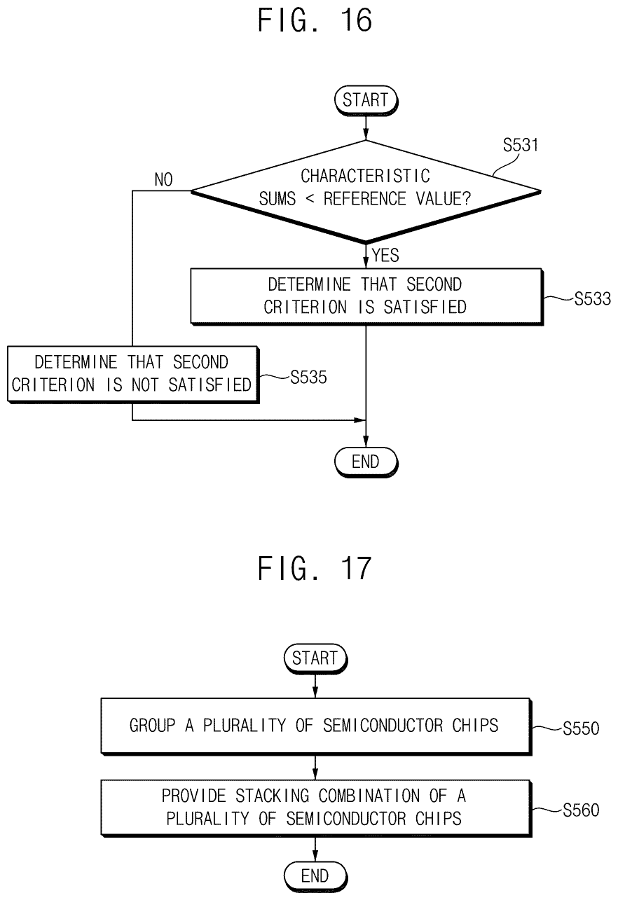

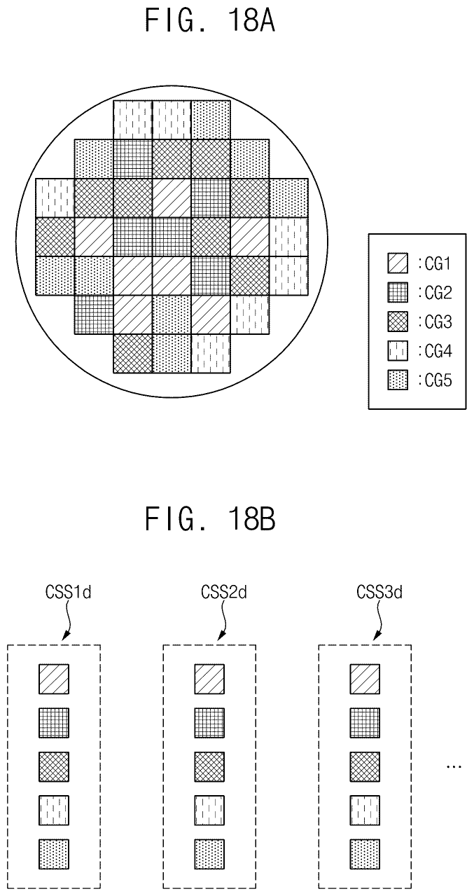

FIG. 17 is a flowchart illustrating an example of recommending a stacking combination of a plurality of semiconductor chips in FIG. 1. FIGS. 18A and 18B are diagrams for describing an operation of FIG. 17.

Referring to FIGS. 1 and 17, when recommending the stacking combination of the plurality of semiconductor chips (operation S500), the plurality of semiconductor chips may be grouped based on the plurality of stress characteristics (operation S550). For example, semiconductor chips having identical and/or similar stress characteristics may be classified into one group, and the plurality of semiconductor chips may be divided into two or more groups, and each semiconductor chip may be included in one group. For example, first semiconductor chips may be divided into and included in a first group, and second semiconductor chips may be divided into and included in a second group.

The stacking combination of the plurality of semiconductor chips may be provided such that the plurality of stacked chip structures have the same configuration (operation S560). For example, one semiconductor chip may be selected from each group, and each stacked chip structure may be formed to include semiconductor chips selected from all groups. For example, a first stacked chip structure may include one of the first semiconductor chips included in the first group and one of the second semiconductor chips included in the second group, and a second stacked chip structure may include another one of the first semiconductor chips included in the first group and another one of the second semiconductor chips included in the second group.

Referring to FIGS. 18A and 18B, an example where operations S550 and S560 in FIG. 17 are performed on semiconductor chips included in one wafer is illustrated.

As illustrated in FIG. 18A, semiconductor chips included in one wafer may be divided or classified into a first group CG1, a second group CG2, a third group CG3, a fourth group CG4 and a fifth group CG5. For example, stress characteristics of semiconductor chips included in the first group CG1 may be less than a first reference value, stress characteristics of semiconductor chips included in the second group CG2 may be greater than or equal to the first reference value and less than a second reference value, stress characteristics of semiconductor chips included in the third group CG3 may be greater than or equal to the second reference value and less than a third reference value, stress characteristics of semiconductor chips included in the fourth group CG4) may be greater than or equal to the third reference value and less than a fourth reference value, and stress characteristics of semiconductor chips included in the fifth group CG5 may be greater than or equal to the fourth reference value.

As illustrated in FIG. 18B, stacked chip structures CSS1d, CSS2d, CSS3d, . . . may be formed such that each stacked chip structure includes one of the semiconductor chips included in the first group CG1, one of the semiconductor chips included in the second group CG2, one of the semiconductor chips included in the third group CG3, one of the semiconductor chips included in the fourth group CG4 and one of the semiconductor chips included in the fifth group CG5. In this example, the sums of stress characteristics of the semiconductor chips included in the stacked chip structures CSS1d, CSS2d, CSS3d, . . . may be equal to or similar each other, and thus the stacked chip structures CSS1d, CSS2d, CSS3d, . . . may satisfy the first criterion and/or the second criterion, as described with reference to FIGS. 12 through 17.

Although the present example has a specific number of semiconductor chips and a specific number of groups, examples are not limited thereto.

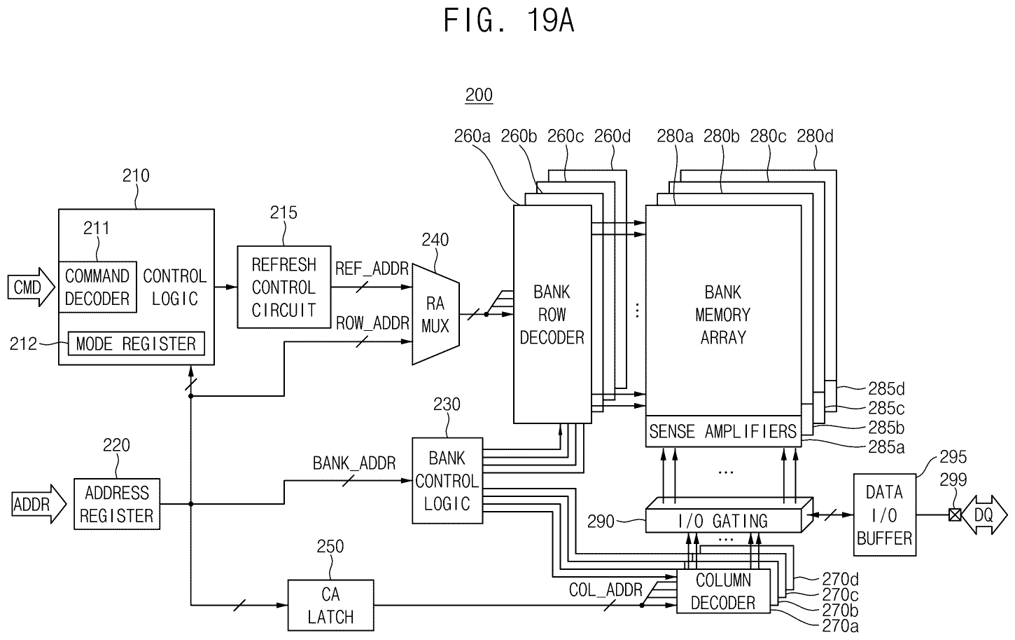

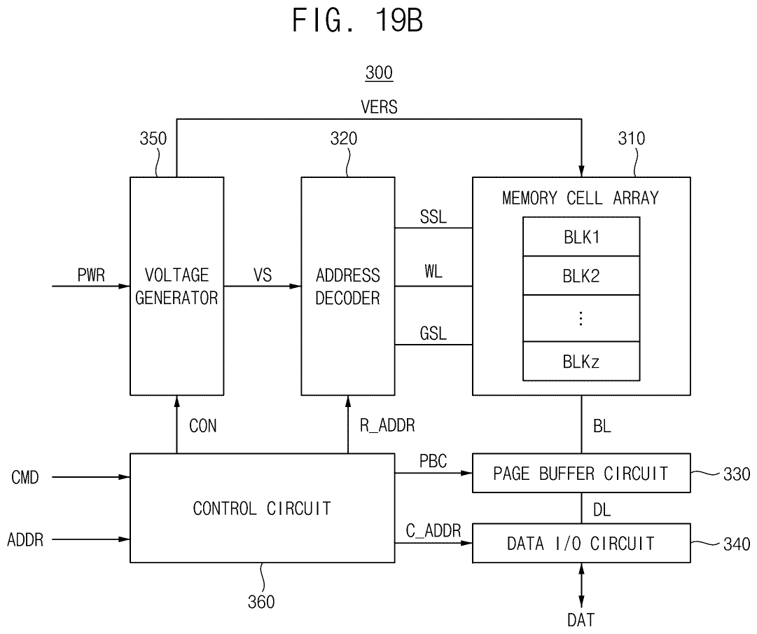

FIGS. 19A and 19B are block diagrams illustrating examples of a semiconductor chip.

Referring to FIG. 19A, an example where the semiconductor chip is or includes a memory (or memory chip) is illustrated. For example, a memory 200 may be one of various volatile memories such as a DRAM.

The memory 200 may include a control logic 210, a refresh control circuit 215, an address register 220, a bank control logic 230, a row address multiplexer 240, a column address latch 250, a row decoder, a column decoder, a memory cell array, a sense amplifier unit, an input/output (I/O) gating circuit 290, a data I/O buffer 295 and a data I/O pad 299.

The memory cell array may include a plurality of memory cells. The memory cell array may include a plurality of bank arrays, e.g., first to fourth bank arrays 280a, 280b, 280c and 280d. The row decoder may include a plurality of bank row decoders, e.g., first to fourth bank row decoders 260a, 260b, 260c and 260d connected to the first to fourth bank arrays 280a, 280b, 280c and 280d, respectively. The column decoder may include a plurality of bank column decoders, e.g., first to fourth bank column decoders 270a, 270b, 270c and 270d connected to the first to fourth bank arrays 280a, 280b, 280c and 280d, respectively. The sense amplifier unit may include a plurality of bank sense amplifiers, e.g., first to fourth bank sense amplifiers 285a, 285b, 285c and 285d connected to the first to fourth bank arrays 280a, 280b, 280c and 280d, respectively.

The first to fourth bank arrays 280a to 280d, the first to fourth bank row decoders 260a to 260d, the first to fourth bank column decoders 270a to 270d, and the first to fourth bank sense amplifiers 285a to 285d may form first to fourth banks, respectively. For example, the first bank array 280a, the first bank row decoder 260a, the first bank column decoder 270a, and the first bank sense amplifier 285a may form the first bank; the second bank array 280b, the second bank row decoder 260b, the second bank column decoder 270b, and the second bank sense amplifier 285b may form the second bank; the third bank array 280c, the third bank row decoder 260c, the third bank column decoder 270c, and the third bank sense amplifier 285c may form the third bank; and the fourth bank array 280d, the fourth bank row decoder 260d, the fourth bank column decoder 270d, and the fourth bank sense amplifier 285d may form the fourth bank.

The address register 220 may receive an address ADDR including a bank address BANK_ADDR, a row address ROW_ADDR and a column address COL_ADDR from a controller located outside the memory 200. The address register 220 may provide the received bank address BANK_ADDR to the bank control logic 230, may provide the received row address ROW_ADDR to the row address multiplexer 240, and may provide the received column address COL_ADDR to the column address latch 250.

The bank control logic 230 may generate bank control signals in response to receipt of the bank address BANK_ADDR. One of the first to fourth bank row decoders 260a to 260d corresponding to the received bank address BANK_ADDR may be activated in response to the bank control signals generated by the bank control logic 230, and one of the first to fourth bank column decoders 270a to 270d corresponding to the received bank address BANK_ADDR may be activated in response to the bank control signals generated by the bank control logic 230.

The refresh control circuit 215 may generate a refresh address REF_ADDR in response to receipt of a refresh command or entrance of any self-refresh mode. For example, the refresh control circuit 215 may include a refresh counter that is configured to sequentially change the refresh address REF_ADDR from a first address of the memory cell array to a last address of the memory cell array. The refresh control circuit 215 may receive control signals from the control logic 210.

The row address multiplexer 240 may receive the row address ROW_ADDR from the address register 220 and may receive the refresh address REF_ADDR from the refresh control circuit 215. The row address multiplexer 240 may selectively output the row address ROW_ADDR or the refresh address REF_ADDR. A row address (e.g., the row address ROW_ADDR or the refresh address REF_ADDR) output from the row address multiplexer 240 may be applied to the first to fourth bank row decoders 260a to 260d.

The activated one of the first to fourth bank row decoders 260a to 260d may decode the row address output from the row address multiplexer 240 and may activate a wordline corresponding to the row address. For example, the activated bank row decoder may apply a wordline driving voltage to the wordline corresponding to the row address.

The column address latch 250 may receive the column address COL_ADDR from the address register 220 and may temporarily store the received column address COL_ADDR. The column address latch 250 may apply the temporarily stored or received column address COL_ADDR to the first to fourth bank column decoders 270a to 270d.

The activated one of the first to fourth bank column decoders 270a to 270d may decode the column address COL_ADDR output from the column address latch 250 and may control the I/O gating circuit 290 to output data corresponding to the column address COL_ADDR.

The I/O gating circuit 290 may include a circuitry for gating I/O data. For example, although not shown, the I/O gating circuit 290 may include an input data mask logic, read data latches for storing data output from the first to fourth bank arrays 280a to 280d, and write drivers for writing data to the first to fourth bank arrays 280a to 280d.

Data DQ to be read from one of the first to fourth bank arrays 280a to 280d may be sensed by a sense amplifier coupled to the one bank array and may be stored in the read data latches. The data DQ stored in the read data latches may be provided to the controller via the data I/O buffer 295 and the data I/O pad 299. Data DQ received via the data I/O pad 299 that are to be written to one of the first to fourth bank arrays 280a to 280d may be provided from the controller to the data I/O buffer 295. The data DQ received via the data I/O pad 299 and provided to the data I/O buffer 295 may be written to the one bank array via the write drivers in the I/O gating circuit 290.

The control logic 210 may control an operation of the memory 200. For example, the control logic 210 may generate control signals for the memory 200 to perform a data write operation or a data read operation. The control logic 210 may include a command decoder 211 that decodes a command CMD received from the controller and a mode register 212 that sets an operation mode of the memory 200.

Referring to FIG. 19B, an example where the semiconductor chip is or includes a memory (or memory chip) is illustrated. For example, a memory 300 may be one of various nonvolatile memories such as a NAND flash memory.

The memory 300 may include a memory cell array 310, an address decoder 320, a page buffer circuit 330, a data input/output (I/O) circuit 340, a voltage generator 350 and a control circuit 360.

The memory cell array 310 may be connected to the address decoder 320 via a plurality of string selection lines SSL, a plurality of wordlines WL and a plurality of ground selection lines GSL. The memory cell array 310 may be further connected to the page buffer circuit 330 via a plurality of bitlines BL. The memory cell array 310 may include a plurality of memory cells (e.g., a plurality of nonvolatile memory cells) that are connected to the plurality of wordlines WL and the plurality of bitlines BL. The memory cell array 310 may be divided into a plurality of memory blocks BLK1, BLK2, . . . , BLKz each of which includes memory cells.

In some implementations, the plurality of memory cells may be arranged in a two-dimensional (2D) array structure or a three-dimensional (3D) vertical array structure. A three-dimensional vertical array structure may include vertical cell strings that are vertically oriented such that at least one memory cell is located over another memory cell. The at least one memory cell may comprise a charge trap layer. The following patent documents, which are hereby incorporated by reference in their entirety, describe suitable configurations for a memory cell array including a 3D vertical array structure, in which the three-dimensional memory array is configured as a plurality of levels, with wordlines and/or bitlines shared between levels: U.S. Pat. Nos. 7,679,133; 8,553,466; 8,654,587; 8,559,235; and US Pat. Pub. No. 2011/0233648.

The control circuit 360 may receive a command CMD and an address ADDR from a controller located outside the memory 300, and may control erasure, programming and read operations of the memory 300 based on the command CMD and the address ADDR. An erasure operation may include performing a sequence of erase loops, and a programming operation may include performing a sequence of program loops. Each program loop may include a program operation and a program verification operation. Each erase loop may include an erase operation and an erase verification operation. The read operation may include a normal read operation and data recovery read operation.

For example, the control circuit 360 may generate control signals CON, which are used for controlling the voltage generator 350, and may generate control signal PBC for controlling the page buffer circuit 330, based on the command CMD, and may generate a row address R_ADDR and a column address C_ADDR based on the address ADDR. The control circuit 360 may provide the row address R_ADDR to the address decoder 320 and may provide the column address C_ADDR to the data I/O circuit 340.

The address decoder 320 may be connected to the memory cell array 310 via the plurality of string selection lines SSL, the plurality of wordlines WL and the plurality of ground selection lines GSL. For example, in the data erase/write/read operations, the address decoder 320 may select at least one of the plurality of wordlines WL as a selected wordline, at least one of the plurality of string selection lines SSL as a selected string selection line, and at least one of the plurality of ground selection lines GSL as a selected ground selection line, based on the row address R_ADDR.

The voltage generator 350 may generate voltages VS that are required for an operation of the memory 300 based on a power PWR and the control signals CON. The voltages VS may be applied to the plurality of string selection lines SSL, the plurality of wordlines WL and the plurality of ground selection lines GSL via the address decoder 320. In addition, the voltage generator 350 may generate an erase voltage VERS that is required for the erase operation based on the power PWR and the control signals CON.

The page buffer circuit 330 may be connected to the memory cell array 310 via the plurality of bitlines BL. The page buffer circuit 330 may include a plurality of page buffers. The page buffer circuit 330 may store data DAT to be programmed into the memory cell array 310 or may read data DAT sensed from the memory cell array 310. In other words, the page buffer circuit 330 may operate as a write driver or a sensing amplifier according to an operation mode of the memory 300.

The data I/O circuit 340 may be connected to the page buffer circuit 330 via data lines DL. The data I/O circuit 340 may provide the data DAT from the outside of the memory 300 to the memory cell array 310 via the page buffer circuit 330 or may provide the data DAT from the memory cell array 310 to the outside of the memory 300, based on the column address C_ADDR.

Although the semiconductor chip is described based on a DRAM and a NAND flash memory, the semiconductor chip may be or include any volatile memory, and/or any nonvolatile memory, e.g., a static random access memory (SRAM), a phase-change random access memory (PRAM), a resistive random access memory (RRAM), a magnetic random access memory (MRAM), a ferroelectric random access memory (FRAM), etc.

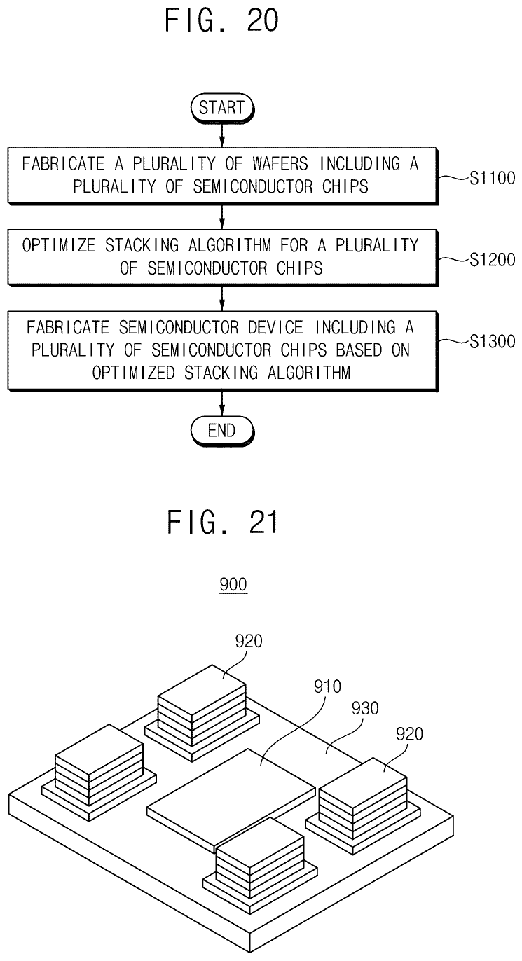

FIG. 20 is a flowchart illustrating an example of a method of manufacturing a semiconductor device.

Referring to FIG. 20, in a method of manufacturing a semiconductor device, a plurality of wafers including a plurality of semiconductor chips are fabricated (operation S1100). For example, the plurality of wafers each of which includes multiple semiconductor chips may be fabricated by semiconductor processes such as an oxidation process, a photolithography process, an etching process, a deposition process, an ion implantation process, a metal wiring process, etc.

A stacking algorithm for the plurality of semiconductor chips is optimized (operation S1200). For example, operation S1200 may be performed based on the method of optimizing the stacking algorithm for the semiconductor chips described with reference to FIGS. 1 through 18B. For example, a plurality of measurement data may be collected from the plurality of wafers using a measuring equipment, a plurality of calculation data may be obtained by pre-processing the plurality of measurement data, a plurality of global stress data associated with the plurality of wafers and a plurality of local stress data associated with the plurality of semiconductor chips may be obtained based on at least one of the plurality of measurement data and the plurality of calculation data, a plurality of stress characteristics associated with the plurality of semiconductor chips may be predicted based on the plurality of global stress data and the plurality of local stress data, and a stacking combination of the plurality of semiconductor chips may be recommended based on the plurality of stress characteristics such that a plurality of stacked chip structures satisfy at least one predetermined criterion. Each of the plurality of stacked chip structures may be formed by stacking two or more of the plurality of semiconductor chips.

The semiconductor device including the plurality of semiconductor chips is fabricated based on the optimized stacking algorithm (operation S1300).

FIG. 21 is a block diagram illustrating an example of a semiconductor device.

Referring to FIG. 21, a semiconductor device 900 may include a first semiconductor chip 910, a plurality of second semiconductor chips 920 and a connection substrate 930.

The first semiconductor chip 910 may control the overall operation of the semiconductor device 900. The plurality of second semiconductor chips 920 may be controlled by the first semiconductor chip 910. The first semiconductor chip 910 and the plurality of second semiconductor chips 920 may be mounted on the connection substrate 930. The first semiconductor chip 910 and the plurality of second semiconductor chips 920 may be electrically connected to each other via the connection substrate 930.

In some implementations, the first semiconductor chip 910 and the plurality of second semiconductor chips 920 may be different types of semiconductor chips. For example, the first semiconductor chip 910 may be or include a processor chip or a logic chip that performs a data processing function, and the plurality of second semiconductor chips 920 may be memory chips that perform a data storage function. For example, the first semiconductor chip 910 may be or include a GPU, the plurality of second semiconductor chips 920 may be or include DRAMs, and the semiconductor device 900 may be a high bandwidth memory (HBM) device. However, examples are not limited thereto.

In the method of optimizing the stacking algorithm for the semiconductor chips, the stress characteristics such as warpage may be efficiently predicted for each semiconductor chip by utilizing the PWG data and the LSC data of the wafers on which the fab-out process is completed. For example, the stress distribution of the thin film may be checked, and the stress may be classified into the global stress causing the warpage of the entire wafer and the local stress at the chip level. For example, the stress characteristics of each semiconductor chip after each semiconductor chip is separated from the wafer may be predicted by reflecting the stress distribution, the thin film structure, the film properties, etc. obtained from the LSC data.

In addition, in the method of optimizing the stacking algorithm for the semiconductor chips, the optimal chip stacking combination may be efficiently recommended based on the predicted stress characteristics (e.g., chip warpage). For example, the stacking combinations of the semiconductor chips with different stress characteristics may be considered, and thus problems such as process risks and yield reduction that may be resolved. For example, the optimal chip stacking combination may be proposed for multiple wafers, and thus wasted semiconductor chips may be minimized and the manufacturing yield may be improved.

The present disclosure may be applied to various semiconductor chips and semiconductor devices and their manufacturing processes, and various electronic devices and systems that include the semiconductor chips and the semiconductor devices. For example, the present disclosure may be applied to electronic devices and systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IOT) device, an internet of everything (IoE) device, an e-book reader, a virtual reality (VR) device, an augmented reality (AR) device, a robotic device, a drone, an automotive, etc.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A method of optimizing a stacking algorithm for semiconductor chips, the method comprising:
collecting, using measuring equipment, measurement data from a plurality of wafers including a plurality of semiconductor chips;
obtaining calculation data based on the measurement data;
obtaining global stress data for the plurality of wafers and local stress data for the plurality of semiconductor chips based on at least one of the measurement data or the calculation data;
determining a plurality of stress characteristics for the plurality of semiconductor chips based on the global stress data and the local stress data; and
determining, based on the plurality of stress characteristics, a stacking combination of the plurality of semiconductor chips to form at least one stacked chip structure that satisfies at least one criterion.

2. The method of claim 1, wherein determining the stacking combination of the plurality of semiconductor chips comprises:
forming a first stacked chip structure including first semiconductor chips and a second stacked chip structure including second semiconductor chips; and
determining that the first stacked chip structure and the second stacked chip structure satisfy a first criterion of the at least one criterion.

3. The method of claim 2, wherein determining that the first stacked chip structure and the second stacked chip structure satisfy the first criterion includes:
determining that a first characteristic sum and a second characteristic sum are equal to each other, the first characteristic sum corresponding to a sum of stress characteristics of the first semiconductor chips, the second characteristic sum corresponding to a sum of stress characteristics of the second semiconductor chips.

4. The method of claim 2, wherein determining that the first stacked chip structure and the second stacked chip structure satisfy the first criterion includes:
determining that a first characteristic sum and a second characteristic sum are within a reference range, the first characteristic sum corresponding to a sum of stress characteristics of the first semiconductor chips, the second characteristic sum corresponding to a sum of stress characteristics of the second semiconductor chips.

5. The method of claim 2, wherein determining the stacking combination of the plurality of semiconductor chips comprises:
determining that the first stacked chip structure and the second stacked chip structure satisfy a second criterion of the at least one criterion.

6. The method of claim 5, wherein determining that the first stacked chip structure and the second stacked chip structure satisfy the second criterion includes:
determining that a first characteristic sum and a second characteristic sum are less than a reference value, the first characteristic sum corresponding to a sum of stress characteristics of the first semiconductor chips, the second characteristic sum corresponding to a sum of stress characteristics of the second semiconductor chips.

7. The method of claim 6, wherein determining the stacking combination of the plurality of semiconductor chips includes:
forming, based on both the first criterion and the second criterion being satisfied, the at least one stacked chip structure that includes the first stacked chip structure and the second stacked chip structure.

8. The method of claim 1, wherein determining the plurality of stress characteristics includes:
obtaining a first stress characteristic of a first semiconductor chip by subtracting first global stress data of a first wafer including the first semiconductor chip from first local stress data of the first semiconductor chip.

9. The method of claim 8, wherein determining the plurality of stress characteristics further includes:
updating the first stress characteristic by determining a change in stress characteristics of the first semiconductor chip after cutting the first wafer to obtain the first semiconductor chip.

10. The method of claim 1, wherein the method is performed before cutting the plurality of wafers to obtain the plurality of semiconductor chips.

11. The method of claim 1, wherein first measurement data of the measurement data includes a first height of a first wafer of the plurality of wafers, and
wherein the first height is a distance between a reference plane to an upper surface of the first wafer at a first measurement position of the first wafer.

12. The method of claim 11, wherein first calculation data of the calculation data is obtained by differentiating the first measurement data twice.

13. The method of claim 1, wherein a number of data points within the measurement data and a number of data points within the calculation data are each greater than or equal to a number of the plurality of semiconductor chips.

14. The method of claim 1, wherein a number of data points within the global stress data is equal to a number of the plurality of wafers, and
wherein a number of data points within the local stress data is equal to a number of the plurality of semiconductor chips.

15. The method of claim 1, wherein semiconductor chips included in a same wafer have same global stress data.

16. The method of claim 1, wherein the plurality of semiconductor chips include a plurality of memory chips.

17. A system comprising:
measuring equipment configured to collect measurement data from a plurality of wafers including a plurality of semiconductor chips;
at least one processor; and
a non-transitory computer readable medium configured to store program codes that, when executed by the at least one processor, cause the system to perform operations comprising:
obtaining calculation data based on the measurement data;
obtaining global stress data for the plurality of wafers and local stress data for the plurality of semiconductor chips based on at least one of the measurement data or the calculation data;
determining a plurality of stress characteristics for the plurality of semiconductor chips based on the global stress data and the local stress data; and
determining, based on the plurality of stress characteristics, a stacking combination of the plurality of semiconductor chips to form at least one stacked chip structure that satisfies at least one criterion.

18. The system of claim 17, wherein the measuring equipment includes non-destructive optical inspecting equipment.

19. A method of manufacturing a semiconductor device, the method comprising:
fabricating a plurality of wafers including a plurality of semiconductor chips;
selecting a stacking combination for the plurality of semiconductor chips; and
fabricating a semiconductor device including the plurality of semiconductor chips based on the selected stacking combination, and
wherein selecting the stacking combination includes:
collecting, using measuring equipment, measurement data from the plurality of wafers;
obtaining calculation data based on the measurement data;
obtaining global stress data for the plurality of wafers and local stress data for the plurality of semiconductor chips based on at least one of the measurement data or of calculation data;
determining a plurality of stress characteristics for the plurality of semiconductor chips based on the global stress data and the local stress data; and
determining, based on the plurality of stress characteristics, the stacking combination to form at least one stacked chip structure that satisfies at least one criterion.

20. The method of claim 19, wherein the plurality of semiconductor chips include a plurality of memory chips, and
wherein the semiconductor device is a high bandwidth memory (HBM) device that includes at least one processor chip and the plurality of memory chips.
